(19) United States
(12) Patent Application Publication
(10) Pub. No.: US 2025/0248180 A1
(43) Pub. Date: Jul. 31, 2025

(54) LIGHT-EMITTING DIODE AND MANUFACTURING METHOD THEREOF

(71) Applicant: EVERLIGHT ELECTRONICS CO., LTD., New Taipei City (TW)

(72) Inventors: Zhong Hai LIN, New Taipei City (TW); Bo Cheng JIANG, New Taipei City (TW)

(21) Appl. No.: 19/026,542

(22) Filed: Jan. 17, 2025

Related U.S. Application Data
(60) Provisional application No. 63/624,967, filed on Jan. 25, 2024.

(30) Foreign Application Priority Data
Dec. 27, 2024 (TW) 113151341

(51) Int. Cl. H10H 20/851; H10H 20/01; H10H 20/854

(52) U.S. Cl. CPC H10H 20/851; H10H 20/0361; H10H 20/0362; H10H 20/854

(57) ABSTRACT

A light-emitting diode includes a substrate, a light-emitting diode chip, a phosphor layer and a protective resin layer. The substrate has a support surface, which includes a central region and a peripheral region surrounding the central region. The peripheral region is at a position lower than the central region in a normal direction of the support surface. The central region and the peripheral region have a step surface in between. The light-emitting diode chip is disposed on the substrate and is electrically connected to the substrate. The phosphor layer is disposed in the central region of the substrate and encapsulates the light-emitting diode chip. The protective resin layer covers at least one exposed surface of the phosphor layer, and covers the peripheral region and the step surface of the substrate.

### RELATED APPLICATIONS

This application claims priority to U.S. Provisional Application Ser. No. 63/624,967, filed Jan. 25, 2024, and Taiwan Application Serial Number 113151341, filed Dec. 27, 2024, the disclosures of which are incorporated herein by reference in their entireties.

### BACKGROUND

### Technical Field

The present disclosure relates to a light-emitting diode and a manufacturing method thereof.

### Description of Related Art

In certain use cases of light-emitting diodes (such as backlight modules for vehicles), in addition to visual effect, reliability of light-emitting diodes is also considered top priority. However, reliability issues are commonly found in commercially available light-emitting diodes, e.g., the phosphor layer is susceptible to degradation due to environmental factors, and the phosphor layer or other layers are prone to detachment due to impact force.

### SUMMARY

In view of the foregoing, one of the objects of the present disclosure is to provide a light-emitting diode having high reliability and a manufacturing method thereof.

In accordance with an embodiment of the present disclosure, a light-emitting diode includes a substrate, a light-emitting diode chip, a phosphor layer and a protective resin layer. The substrate has a support surface which includes a central region and a peripheral region surrounding the central region. The peripheral region is at a position lower than the central region in a normal direction of the support surface. The central region and the peripheral region have a step surface in between. The light-emitting diode chip is disposed on the substrate and is electrically connected to the substrate. The phosphor layer is disposed in the central region of the substrate and encapsulates the light-emitting diode chip. The protective resin layer covers at least one exposed surface of the phosphor layer and covers the peripheral region and the step surface of the substrate.

In one or more embodiments of the present disclosure, the phosphor layer has a lower surface, an upper surface and at least one lateral surface. The lower surface faces the substrate. The upper surface is opposite to the lower surface. The lateral surface is connected between the lower surface and the upper surface. The protective resin layer covers the upper surface and the lateral surface of the phosphor layer.

In one or more embodiments of the present disclosure, the light-emitting diode further includes a light blocking layer covering the upper surface of the phosphor layer. The protective resin layer covers the lateral surface of the phosphor layer.

In one or more embodiments of the present disclosure, the protective resin layer further encapsulates the light blocking layer.

In one or more embodiments of the present disclosure, the protective resin layer has an upper surface, at least one lateral surface, and at least one sloping surface connected between the upper surface and the lateral surface.

In one or more embodiments of the present disclosure, a thickness of the protective resin layer falls within a range from 0.1 μm to 1000 μm.

In one or more embodiments of the present disclosure, an optical transmission coefficient of the protective resin layer is greater than fifty percent.

In one or more embodiments of the present disclosure, the step surface between the central region and the peripheral region is flush with a lateral surface of the phosphor layer.

In one or more embodiments of the present disclosure, a ratio of a height difference between the central region and the peripheral region to a maximum thickness of the substrate falls within a range from 0.4 to 0.8.

In one or more embodiments of the present disclosure, the substrate has a first lateral surface on an outer side of the peripheral region. The protective resin layer has a second lateral surface substantially flush with the first lateral surface of the substrate. The first lateral surface of the substrate is free of coverage by the protective resin layer.

In one or more embodiments of the present disclosure, the peripheral region being at a position lower than the central region creates a stepped structure along a perimeter of the substrate.

In accordance with an embodiment of the present disclosure, a method for manufacturing light-emitting diodes includes: (I) providing a plurality of light-emitting diode chips on a substrate; (II) forming a phosphor layer covering the substrate and the light-emitting diode chips; (III) performing a first cutting operation, resulting in creation of a groove in the phosphor layer around each of the light-emitting diode chips, and resulting in creation of a recess in the substrate aligned with the groove; (IV) forming a protective resin layer, the protective resin layer filling the groove and the recess and covering at least one lateral surface of the phosphor layer; and (V) performing a second cutting operation, including cutting entirely through the protective resin layer and the substrate from a position between two sidewalls of the groove, thereby forming a plurality of light-emitting diodes.

In one or more embodiments of the present disclosure, the recess has two side surfaces and a bottom surface, all of which are covered by the protective resin layer. A cutting path of the second cutting operation passes through the bottom surface of the recess, such that the two side surfaces of the recess belong to two of the light-emitting diodes after the second cutting operation.

In one or more embodiments of the present disclosure, a ratio of a depth of the recess to a maximum thickness of the substrate falls within a range from 0.4 to 0.8.

In one or more embodiments of the present disclosure, in the step of forming the protective resin layer, the protective resin layer further covers an upper surface of the phosphor layer.

In sum, the light-emitting diode of the present disclosure includes a protective resin layer that covers at least one exposed surface of the phosphor layer. The protective resin layer can provide protection to the phosphor layer, such that degradation of the phosphor layer can be slowed down. In addition, the protective resin layer can reduce the likelihood of detachment of the phosphor layer or other layers of the light-emitting diode when an impact force acts on the light-emitting diode.

### BRIEF DESCRIPTION OF THE DRAWINGS

To make the objectives, features, advantages, and embodiments of the present disclosure, including those mentioned above and others, more comprehensible, descriptions of the accompanying drawings are provided as follows.

FIG. 1 illustrates a schematic sectional view of a light-emitting diode in accordance with an embodiment of the present disclosure;

FIGS. 2-6 illustrate schematic sectional views of various stages of a method for manufacturing light emitting diodes in accordance with an embodiment of the present disclosure;

FIG. 7 illustrates a schematic sectional view of a light-emitting diode in accordance with another embodiment of the present disclosure;

FIG. 8 illustrates a schematic sectional view of a light-emitting diode in accordance with another embodiment of the present disclosure; and

FIG. 9 illustrates a schematic sectional view of a light-emitting diode in accordance with another embodiment of the present disclosure.

### DETAILED DESCRIPTION

For the completeness of the description of the present disclosure, reference is made to the accompanying drawings and the various embodiments described below. Various features in the drawings are not drawn to scale and are provided for illustration purposes only. To provide full understanding of the present disclosure, various practical details will be explained in the following descriptions. However, a person with an ordinary skill in relevant art should realize that the present disclosure can be implemented without one or more of the practical details. Therefore, the present disclosure is not to be limited by these details.

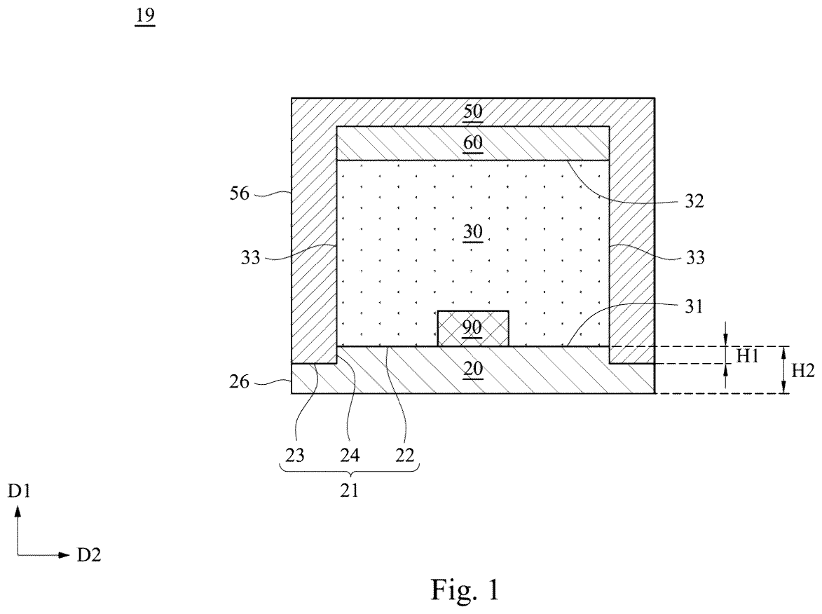

Reference is made to FIG. 1. FIG. 1 illustrates a schematic sectional view of a light-emitting diode 19 in accordance with an embodiment of the present disclosure. The light-emitting diode 19 of the present disclosure is a light-emitting diode package. The light-emitting diode 19 includes a substrate 20 and at least one light-emitting diode chip 90. The light-emitting diode chip 90 is disposed on the substrate 20 and is electrically connected to the substrate 20. The substrate 20 has a support surface 21, and the light-emitting diode chip 90 is disposed on the support surface 21. In other words, the support surface 21 is a surface of the substrate 20 facing the light-emitting diode chip 90.

In some embodiments, the substrate 20 includes a base material, such as epoxy molding compound (EMC) or other resin material, and at least one conductive structure disposed on the surface or the interior of the base material. The conductive structure may include electrodes exposed from a lower side of the substrate 20 and configured to be coupled to an external device, such as a circuit board. In some embodiments, the light-emitting diode chip 90 can be electrically coupled to the substrate 20 by means of wire bonding. In some embodiments, the light-emitting diode chip 90 can be electrically coupled to the substrate 20 by means of flip-chip bonding.

As shown in FIG. 1, the support surface 21 of the substrate 20 is uneven. Specifically, the support surface 21 includes a central region 22 and a peripheral region 23 surrounding the central region 22. The peripheral region 23 is at a position lower than the central region 22 in a normal direction of the support surface 21, which may coincide with a first direction D1 shown in the drawings. The central region 22 and the peripheral region 23 have a step surface 24 in between. The peripheral region 23 is connected to the central region 22 via the step surface 24. In some embodiments, in the first direction D1, a ratio of a height difference H1 between the central region 22 and the peripheral region 23 to a maximum thickness H2 of the substrate 20 (e.g., a distance from the central region 22 to a lower surface of the substrate 20) falls within a range from 0.4 to 0.8.

As shown in FIG. 1, in some embodiments, the peripheral region 23 being at a position lower than the central region 22 creates a stepped structure along a perimeter of the substrate 20. Specifically, the substrate 20 further has at least one lateral surface 26 connected to the peripheral region 23 and located on an outer side of the peripheral region 23. The central region 22, the step surface 24, the peripheral region 23 and the lateral surface 26 have a stepped profile. In some embodiments, the stepped structure of the substrate 20 can be formed by cutting. The method of manufacturing the light-emitting diode 19 will be described in detail below. In some embodiments, in a top view of the light-emitting diode 19, the substrate 20 is substantially rectangular, and the stepped structure is arranged along four edges of the substrate 20.

In some embodiments, the substrate 20 includes a first portion and a second portion connected to the first portion. In the first direction D1, the first portion is stacked on the second portion. The second portion laterally extends beyond the first portion. In other words, in a second direction D2 substantially normal to the first direction D1, the second portion extends beyond the first portion. The first portion may correspond to the central region 22 of the substrate 20. An outer part of the second portion, which extends beyond a perimeter of the first portion, may correspond to the peripheral region 23 of the substrate 20.

As shown in FIG. 1, the light-emitting diode chip 90 is disposed in the central region 22 of the support surface 21 of the substrate 20. The light-emitting diode chip 90 and the substrate 20 are stacked in the first direction D1. The light-emitting diode 19 further includes a phosphor layer 30 disposed in the central region 22 of the support surface 21 of the substrate 20 and encapsulating the light-emitting diode chip 90. In other words, the light-emitting diode chip 90 is disposed in the interior of the phosphor layer 30. In some embodiments, the phosphor layer 30 completely covers the central region 22 of the support surface 21 of the substrate 20. In some embodiments, an orthogonal projection area of the phosphor layer 30 on the substrate 20 matches the central region 22. In some embodiments, the phosphor layer 30 is spaced apart from the peripheral region 23 and the step surface 24. In other words, the phosphor layer 30 does not contact the peripheral region 23 and the step surface 24.

In some embodiments, the phosphor layer 30 may include a transparent resin material and phosphor powder distributed in the transparent resin material. The phosphor powder may include CaAlSiN₃:Eu²⁺, (Sr,Ca)AlSiN₃:Eu²⁺, CaS:Eu²⁺, Sr₃Si(ON)₅:Eu²⁺, K₂SiF₆:Mn⁴⁺, CaSc₂O₄:Ce²⁺, SrGa₂S:Eu²⁺, TAG, YAG, Sr₂SiO₄:Eu²⁺, other suitable materials, or any combination thereof.

As shown in FIG. 1, the light-emitting diode 19 further includes a protective resin layer 50 covering at least one exposed surface of the phosphor layer 30. The protective resin layer 50 can enhance the reliability of the light-emitting diode 19. For example, the protective resin layer 50 may help improve waterproof capability and impact resistance of the light-emitting diode 19, and can prevent accelerated degradation of the phosphor layer 30 due to environmental factors (e.g., temperature and humidity). Furthermore, the protective resin layer 50 covers and contacts the peripheral region 23 and the step surface 24 of the substrate 20. Hence, the protective resin layer 50 and the substrate 20 have a strong binding force, and the protective resin layer 50 would not easily detach from the substrate 20. Accordingly, the light-emitting diode 19 of the present disclosure is suitable for applications with relatively strict requirement for reliability, such as automotive environment.

The protective resin layer 50 may include transparent or semi-transparent resin material. For example, the protective resin layer 50 may include silica, epoxy or acrylic. In some embodiments, an optical transmission coefficient of the protective resin layer 50 is greater than fifty percent. In some embodiments, a thickness of the protective resin layer falls within a range from 0.1 μm to 1000 μm.

As shown in FIG. 1, in some embodiments, the substrate 20 has a notch located at the perimeter of the substrate 20. The notch corresponds to the stepped structure mentioned above. The protective resin layer 50 is partially located below the phosphor layer 30 and fills into the notch. In some embodiments, the protective resin layer 50 completely fills the notch. In some embodiments, the protective resin layer 50 has a lateral surface 56 substantially flush with the lateral surface 26 of the substrate 20. The lateral surface 26 of the substrate 20 is free of coverage by the protective resin layer 50. In other words, the protective resin layer 50 neither contacts nor covers the lateral surface 26 of the substrate 20.

As shown in FIG. 1, in the present embodiment, the phosphor layer 30 has a lower surface 31, an upper surface 32 and at least one lateral surface 33. The lower surface 31 faces the substrate 20. The upper surface 32 is opposite to the lower surface 31. In other words, the upper surface 32 is a surface of the phosphor layer 30 away from the substrate 20. The lateral surface 33 is connected between the lower surface 31 and the upper surface 32. The lateral surface 33 is substantially flush with the step surface 24 of the substrate 20. The light-emitting diode 19 further includes a light blocking layer 60 covering the upper surface 32 of the phosphor layer 30. The protective resin layer 50 covers the lateral surface 33 of the phosphor layer 30. In some embodiments, in a top view of the light-emitting diode 19, the phosphor layer 30 is substantially rectangular, and the protective resin layer 50 covers four lateral surfaces 33 of the phosphor layer 30.

The upper surface 32 of the phosphor layer 30 is covered by the light blocking layer 60. Therefore, after light emitted by the light-emitting diode chip 90 enters the phosphor layer 30 and undergoes wavelength conversion, light mainly (or only) outputs from the lateral surface 33 of the phosphor layer 30. By this arrangement, the light-emitting diode 19 can output light more uniformly. Moreover, the light blocking layer 60 can also provide protection for the phosphor layer 30. The light blocking layer 60 prevents exposure of the upper surface 32 of the phosphor layer 30. The light blocking layer 60 may include a resin material and opaque particles (e.g., Titanium dioxide particles) distributed in the resin material. The protective resin layer 50 differs from the light blocking layer 60 in that the protective resin layer 50 does not include any opaque particles. The protective resin layer 50 does not include any phosphor powder either.

As shown in FIG. 1, in some embodiments, the protective resin layer 50 further encapsulates the light blocking layer 60. In other words, the protective resin layer 50 also covers an upper surface and at least one lateral surface of the light blocking layer 60. In other embodiments, the protective resin layer 50 may not cover the light blocking layer 60. Such embodiment will be described in more detail below.

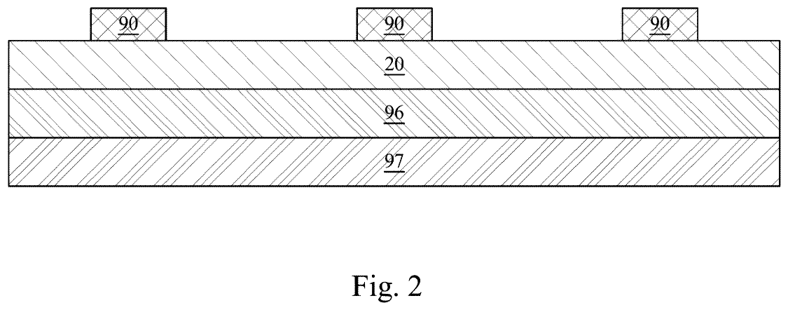

FIGS. 2-6 illustrate schematic sectional views of various stages of a method for manufacturing light emitting diodes in accordance with an embodiment of the present disclosure. The method may include steps S1 to S7.

As shown in FIG. 2, the method begins at step S1, which includes: providing a plurality of light-emitting diode chips 90 on a substrate 20, in which the substrate 20 is temporarily attached to a mounting plate 97 via a pyrolytic adhesive tape 96. The mounting plate 97 is, for example, a steel plate. In some embodiments, step S1 includes a chip attachment operation (e.g., using an adhesive to attach the light-emitting diode chips 90 to the substrate 20) followed by a wire bonding operation (e.g., using bonding wires to electrically connect the positive and negative electrodes of the light-emitting diode chips 90 to the substrate 20).

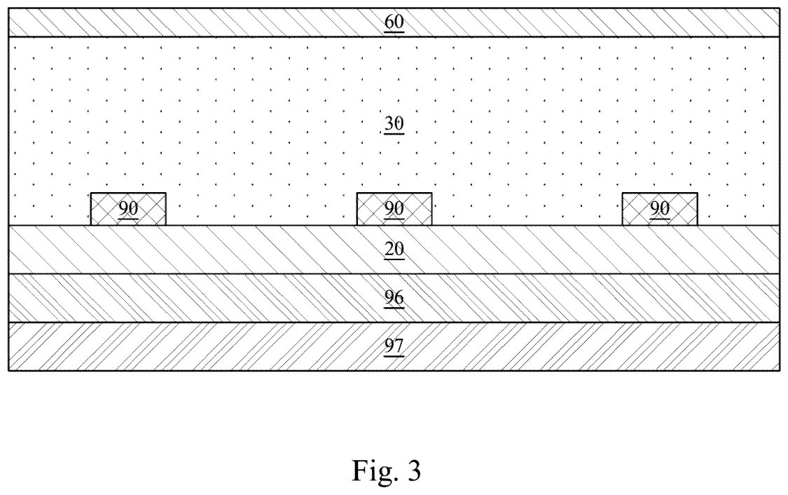

As shown in FIG. 3, the next step is step S2, which includes forming a phosphor layer 30. The phosphor layer 30 is disposed over the substrate 20 and covers the substrate 20 and the light-emitting diode chips 90. In some embodiments, step S2 includes: (1) forming a temporary phosphor layer by dispensing, molding, spray coating or other suitable techniques; and (2) planarizing an upper surface of the temporary phosphor layer to form the phosphor layer 30 (e.g., using a planer blade to smooth the upper surface of the temporary phosphor layer).

As shown in FIG. 3, the next step is step S3, which includes forming a light blocking layer 60. The light blocking layer 60 is disposed over the phosphor layer 30 and covers the upper surface of the phosphor layer 30. In some embodiments, step S3 includes: (1) forming a temporary light blocking layer by dispensing, molding, spray coating or other suitable techniques; and (2) planarizing an upper surface of the temporary light blocking layer to form the light blocking layer 60 (e.g., using a planer blade to smooth the upper surface of the temporary light blocking layer).

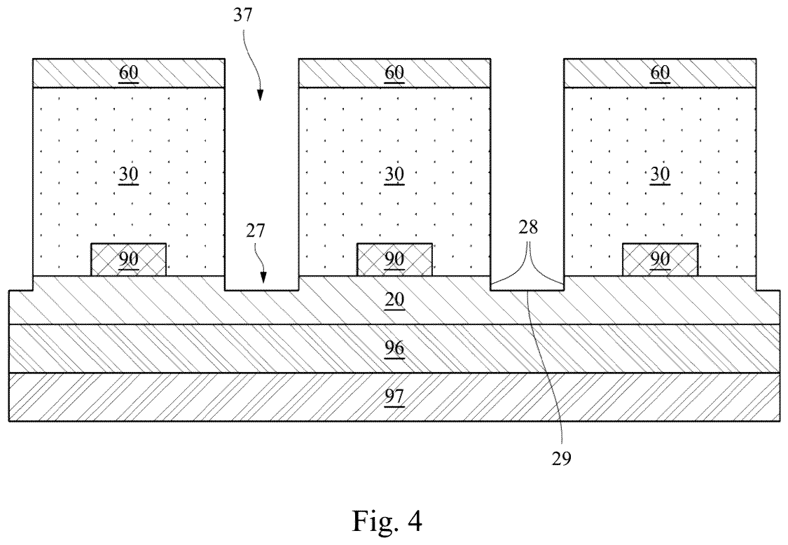

As shown in FIG. 4, the next step is step S4, which includes: performing a first cutting operation, resulting in creation of a groove 37 in the phosphor layer 30 around each of the light-emitting diode chips 90, and resulting in creation of a recess 27 in the substrate 20 aligned with the groove 37. In addition, the first cutting operation also results in creation of a groove in the light blocking layer 60 around each of the light-emitting diode chips 90.

It is noted that in step S4, the light blocking layer 60 and the phosphor layer 30 are cut entirely through, but the substrate 20 is not. In other words, the recess 27 does not penetrate through the substrate 20. The recess 27 has a bottom surface 29 and two side surfaces 28 connected to the bottom surface 29. The bottom surface 29 of the recess 27 is spaced apart from the pyrolytic adhesive tape 96. By this arrangement, in the subsequent step of forming the protective resin layer 50 (will be introduced below), the resin can be prevented from leaking to the lower side of the substrate 20 and causing failure (e.g., unable to light up) of the light-emitting diode 19. Accordingly, product yield can be improved. In some embodiments, in a stacking direction of the substrate 20 and the light-emitting diode chips 90, a ratio of a depth of the recess 27 to a maximum thickness of the substrate 20 falls within a range from 0.4 to 0.8. By this arrangement, the subsequently formed protective resin layer 50 can be guaranteed to have a strong binding force with the substrate 20, and meanwhile preventing accidentally cutting entirely through the substrate 20. In some embodiments, the first cutting operation can be carried out by a cutting blade or a laser cutting device.

It is noted that the recess 27 formed in the substrate 20 in step S4 corresponds to the peripheral region 23 and the step surface 24 of the substrate 20 of the light-emitting diode 19 shown in FIG. 1 (which is a finished product). In addition, in FIG. 4, the part of the substrate 20 excluding the recess 27 corresponds to the central region 22 of the substrate 20 of the light-emitting diode 19 shown in FIG. 1.

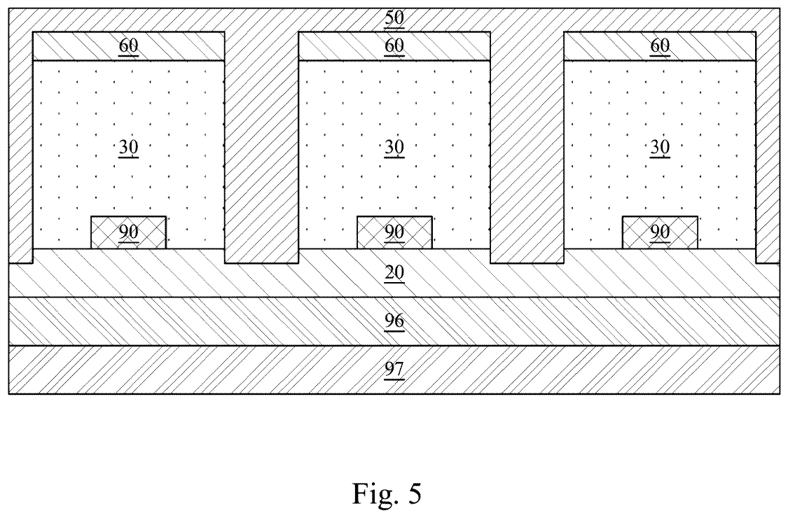

As shown in FIG. 5, the next step is step S5, which includes forming a protective resin layer 50. The protective resin layer 50 fills the groove 37 of the phosphor layer 30 and the recess 27 of the substrate 20 mentioned above, and the protective resin layer 50 covers at least one lateral surface of the phosphor layer 30. Specifically, the bottom surface 29 and the two side surfaces 28 of the recess 27 (see FIG. 4) are covered by the protective resin layer 50. In addition, the protective resin layer 50 fills the groove of the light blocking layer 60 mentioned above and covers the upper surface of the light blocking layer 60 (as a result, the protective resin layer 50 indirectly covers the upper surface of the phosphor layer 30). In some embodiments, the protective resin layer 50 can be formed by dispensing, molding, spray coating or other suitable techniques.

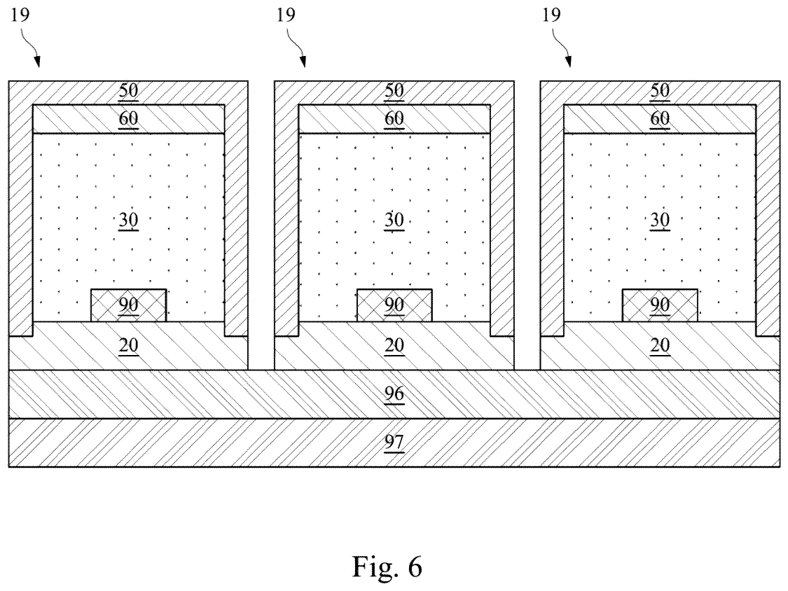

As shown in FIG. 6, the next step is step S6, which includes: performing a second cutting operation, including cutting entirely through the protective resin layer 50 and the substrate 20 from a position between two sidewalls of the groove 37 of the phosphor layer 30 mentioned above (see FIG. 4), thereby forming a plurality of light-emitting diodes 19 separated from one another. A cutting path of the second cutting operation passes through the bottom surface 29 of the recess 27 mentioned above (see FIG. 4), such that the two side surfaces 28 of the recess 27 belong to two different the light-emitting diodes 19 after the second cutting operation. As a result, upon completion of the second cutting operation, the aforementioned stepped structure is formed along the perimeter of the substrate 20 of each of the light-emitting diodes 19, and the protective resin layer 50 is attached to the stepped structure. In some embodiments, the second cutting operation can be carried out by a cutting blade or a laser cutting device. In some embodiments, the second cutting operation has a smaller cutting width than the first cutting operation.

The method ends at step S7, which includes: separating the light-emitting diodes 19 from the mounting plate 97. In some embodiments, step S7 includes heating the pyrolytic adhesive tape 96 to allow the light-emitting diodes 19 to detach from the mounting plate 97.

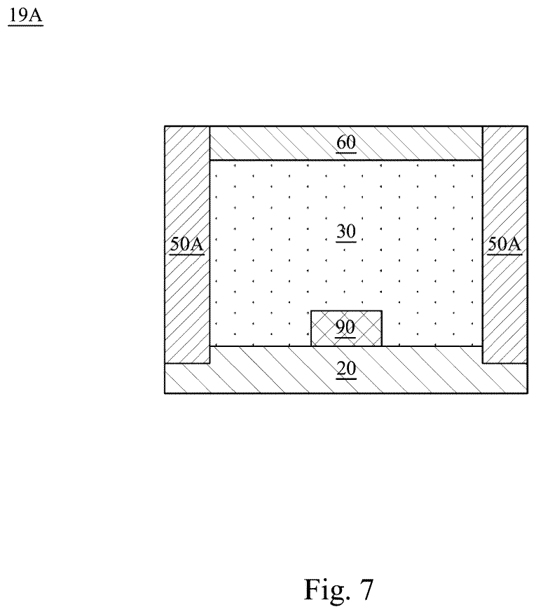

FIG. 7 illustrates a schematic sectional view of a light-emitting diode 19A in accordance with another embodiment of the present disclosure. The light-emitting diode 19A of the present embodiment includes a substrate 20, a light-emitting diode chip 90, a phosphor layer 30, a protective resin layer 50A and a light blocking layer 60. The present embodiment differs from the embodiment shown in FIG. 1 in that the protective resin layer 50A covers the lateral surface of the phosphor layer 30 but does not cover an upper surface of the light blocking layer 60. In other words, the protective resin layer 50A is spaced apart from the upper surface of the light blocking layer 60. Such structure can also achieve the objective of protecting the phosphor layer 30 and thus makes the light-emitting diode 19A highly reliable.

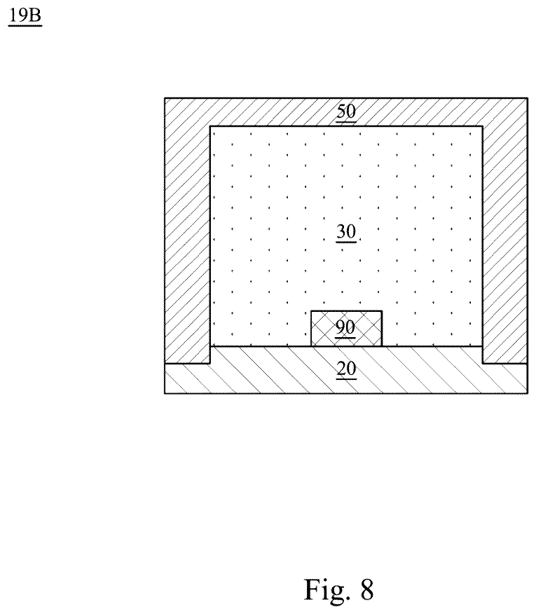

FIG. 8 illustrates a schematic sectional view of a light-emitting diode 19B in accordance with another embodiment of the present disclosure. The light-emitting diode 19B of the present embodiment includes a substrate 20, a light-emitting diode chip 90, a phosphor layer 30 and a protective resin layer 50. The present embodiment differs from the embodiment shown in FIG. 1 in that the light-emitting diode 19B does not include the light blocking layer 60, and the protective resin layer 50 directly covers the upper surface of the phosphor layer 30. In other words, the protective resin layer 50 covers and contacts the upper surface of the phosphor layer 30. By this arrangement, after light emitted by the light-emitting diode chip 90 enters the phosphor layer 30 and undergoes wavelength conversion, light can output from both the lateral surface and the upper surface of the phosphor layer 30. In addition, such structure can also achieve the objective of protecting the phosphor layer 30 and thus makes the light-emitting diode 19B highly reliable.

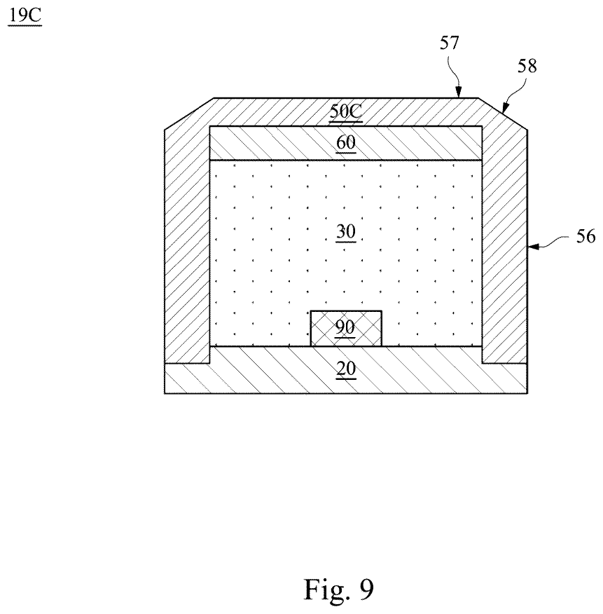

FIG. 9 illustrates a schematic sectional view of a light-emitting diode 19C in accordance with another embodiment of the present disclosure. The light-emitting diode 19C of the present embodiment includes a substrate 20, a light-emitting diode chip 90, a phosphor layer 30, a protective resin layer 50C and a light blocking layer 60. The present embodiment differs from the embodiment shown in FIG. 1 in that the protective resin layer 50C has (I) an upper surface 57 located on a side of the protective resin layer 50C away from the substrate 20, (II) at least one lateral surface 56 connected to the substrate 20 and substantially normal to the substrate 20, and (III) at least one sloping surface 58 connected between the upper surface 57 and the lateral surface 56. The sloping surface 58 is at an angle to (i.e., not parallel to) the upper surface 57 and the lateral surface 56. By this arrangement, the protective resin layer 50C can not only protect the phosphor layer 30 but also act as a lens-like structure. Area, slope or other parameters of the sloping surface 58 can be adjusted as needed to achieve desirable visual or optical effect.

In sum, the light-emitting diode of the present disclosure includes a protective resin layer that covers at least one exposed surface of the phosphor layer. The protective resin layer can provide protection to the phosphor layer, such that degradation of the phosphor layer can be slowed down. In addition, the protective resin layer can reduce the likelihood of detachment of the phosphor layer or other layers of the light-emitting diode when an impact force acts on the light-emitting diode.

Although the present disclosure has been described by way of the exemplary embodiments above, the present disclosure is not to be limited to those embodiments. Any person skilled in the art can make various changes and modifications without departing from the spirit and the scope of the present disclosure. Therefore, the protective scope of the present disclosure shall be the scope of the claims as attached.

What is claimed is:

1. A light-emitting diode, comprising:
a substrate having a support surface, the support surface comprising a central region and a peripheral region surrounding the central region, wherein the peripheral region is at a position lower than the central region in a normal direction of the support surface, and the central region and the peripheral region have a step surface in between;
a light-emitting diode chip disposed on the substrate and electrically connected to the substrate;
a phosphor layer disposed in the central region of the substrate and encapsulating the light-emitting diode chip; and
a protective resin layer covering at least one exposed surface of the phosphor layer and covering the peripheral region and the step surface of the substrate.

2. The light-emitting diode of claim 1, wherein the phosphor layer has a lower surface, an upper surface and at least one lateral surface, the lower surface faces the substrate, the upper surface is opposite to the lower surface, the at least one lateral surface is connected between the lower surface and the upper surface, and the protective resin layer covers the upper surface and the at least one lateral surface of the phosphor layer.

3. The light-emitting diode of claim 1, wherein the phosphor layer has a lower surface, an upper surface and at least one lateral surface, the lower surface faces the substrate, the upper surface is opposite to the lower surface, the at least one lateral surface is connected between the lower surface and the upper surface, wherein the light-emitting diode further comprises a light blocking layer covering the upper surface of the phosphor layer, and the protective resin layer covers the at least one lateral surface of the phosphor layer.

4. The light-emitting diode of claim 3, wherein the protective resin layer further encapsulates the light blocking layer.

5. The light-emitting diode of claim 1, wherein the protective resin layer has an upper surface, at least one lateral surface, and at least one sloping surface connected between the upper surface and the at least one lateral surface.

6. The light-emitting diode of claim 1, wherein a thickness of the protective resin layer falls within a range from 0.1 μm to 1000 μm.

7. The light-emitting diode of claim 1, wherein an optical transmission coefficient of the protective resin layer is greater than fifty percent.

8. The light-emitting diode of claim 1, wherein the step surface between the central region and the peripheral region is flush with a lateral surface of the phosphor layer.

9. The light-emitting diode of claim 1, wherein a ratio of a height difference between the central region and the peripheral region to a maximum thickness of the substrate falls within a range from 0.4 to 0.8.

10. The light-emitting diode of claim 1, wherein the substrate has a first lateral surface on an outer side of the peripheral region, the protective resin layer has a second lateral surface substantially flush with the first lateral surface of the substrate, and the first lateral surface of the substrate is free of coverage by the protective resin layer.

11. The light-emitting diode of claim 1, wherein the peripheral region being at a position lower than the central region creates a stepped structure along a perimeter of the substrate.

12. A method for manufacturing light-emitting diodes, comprising:
providing a plurality of light-emitting diode chips on a substrate;
forming a phosphor layer covering the substrate and the light-emitting diode chips;
performing a first cutting operation, resulting in creation of a groove in the phosphor layer around each of the light-emitting diode chips, and resulting in creation of a recess in the substrate aligned with the groove;
forming a protective resin layer, the protective resin layer filling the groove and the recess and covering at least one lateral surface of the phosphor layer; and
performing a second cutting operation, comprising cutting entirely through the protective resin layer and the substrate from a position between two sidewalls of the groove, thereby forming a plurality of light-emitting diodes.

13. The method of claim 12, wherein the recess has two side surfaces and a bottom surface, all of which are covered by the protective resin layer, wherein a cutting path of the second cutting operation passes through the bottom surface of the recess, such that the two side surfaces of the recess belong to two of the light-emitting diodes after the second cutting operation.

14. The method of claim 12, wherein a ratio of a depth of the recess to a maximum thickness of the substrate falls within a range from 0.4 to 0.8.

15. The method of claim 12, wherein in the step of forming the protective resin layer, the protective resin layer further covers an upper surface of the phosphor layer.

16. The method of claim 12, wherein a thickness of the protective resin layer falls within a range from 0.1 μm to 1000 μm.

17. The method of claim 12, wherein an optical transmission coefficient of the protective resin layer is greater than fifty percent.

18. The method of claim 12, wherein a stepped structure is formed along a perimeter of the substrate of each of the light-emitting diodes upon completion of the second cutting operation, and the protective resin layer is attached to the stepped structure.

19. The method of claim 12, wherein the second cutting operation has a smaller cutting width than the first cutting operation.

20. The method of claim 12, wherein the first cutting operation and the second cutting operation are carried out by a cutting blade or a laser cutting device.
